(19) United States
(12) Patent Application Publication
(10) Pub. No.: US 2026/0371957 A1
(43) Pub. Date: Nov. 19, 2026

(54) METHOD FOR STABILIZING A SURFACE OF A SEMICONDUCTOR MATERIAL

(71) Applicants: Soitec, BERNIN (FR); COMMISSARIAT A L'ENERGIE ATOMIQUE ET AUX ENERGIES ALTERNATIVES, PARIS (FR)

(72) Inventors: Gweltaz Gaudin, BERNIN (FR); Oleg Kononchuk, BERNIN (FR); Djamel Belhachemi, BERNIN (FR); Emmanuel Rolland, Grenoble (FR); Alexandre Moulin, Grenoble (FR); Christelle Navone, Grenoble (FR); Jérémy Roi, BERNIN (FR); Damien Massy, BERNIN (FR)

(21) Appl. No.: 19/139,591

(22) PCT Filed: Dec. 14, 2023
(86) PCT No.: PCT/FR2023/052011

§ 371 Date: Jun. 16, 2025

(30) Foreign Application Priority Data
Dec. 14, 2022 (FR) 2213349

(51) Int. Cl. H10P 14/69; H10P 14/60; H10P 50/28; H10P 95/40

(52) U.S. Cl. CPC H10P 14/6902; H10P 14/6332; H10P 14/6334; H10P 50/283; H10P 95/40

(57) ABSTRACT

A method for stabilizing a surface of a semiconductor material, in particular a monocrystalline semiconductor material, against the formation of terraces and/or beads, includes the formation, on the surface, of a vitreous carbon layer in the gaseous phase at a pressure greater than or equal to 80 kPa (800 mbar).

### CROSS-REFERENCE TO RELATED APPLICATIONS

This application is a national phase entry under 35 U.S.C. § 371 of International Patent Application PCT/FR2023/052011, filed Dec. 14, 2023, designating the United States of America and published as International Patent Publication WO 2024/126954 A1 on Jun. 20, 2024, which claims the benefit under Article 8 of the Patent Cooperation Treaty of French Patent Application Serial No. FR2213349, filed Dec. 14, 2022.

### TECHNICAL FIELD

The present disclosure concerns a method for stabilizing a surface of a semiconductor material, in particular, a monocrystalline semiconductor material. The present disclosure further relates to a method of heat treatment and a method of manufacturing a semiconductor structure comprising a step of stabilizing a surface of a semiconductor material, in particular, a monocrystalline semiconductor material.

### BACKGROUND

Semiconductor materials, in particular, silicon carbide (SiC), are widely used for the manufacture of electronic power or radiofrequency components. In some applications, solid monocrystalline SiC substrates, substrates with a monocrystalline SiC surface layer, or substrates containing other semiconductor materials such as aluminum nitride (AlN), gallium nitride (GaN), alloys of these nitrides, indium phosphide (InP) or gallium arsenide (GaAs) are used. In some cases, the semiconductor substrates or semiconductor layers are polycrystalline.

Substrates for electronic applications often require heat treatments during their manufacture, for example, annealing to heal defects in the crystal lattice caused during implantation of ionic species or to modify the crystal structure of the substrate. Such treatments are often carried out at high temperatures able to reach 2000 °C.

However, the surface of the semiconductor materials considered is liable to become destabilized under the effect of high temperature. This destabilization may be reflected by degradation of the surface, especially by a modification of the morphology and/or composition thereof.

In particular, as illustrated in FIG. 1, smooth SiC surfaces are sensitive to high temperature treatments, typically from approximately 1300 °C. In the absence of adequate protection of the surface, the morphology reorganizes to minimize the surface energy, forming terraces 22. This effect is known as step bunching. The reorganization of the surface 222 is due to a diffusion of the atoms on the surface when it is exposed to high temperatures. It further depends on the atmosphere and pressure to which the surface is exposed. It also depends on the disorientation angle of the surface with regard to an axis of high symmetry of the crystal of the semiconductor material. Such disorientation is used to facilitate the control of the 4H polytype of SiC during subsequent epitaxy of monocrystalline SiC and to prevent polytype changes during monocrystalline SiC growth. An angle of 4° is often chosen for such an epitaxy process. However, the greater this angle of inclination, the higher the steps between the terraces 22.

Such disorientations can also occur spontaneously on a polycrystalline SiC surface, whose grain orientation is random.

The surfaces of other semiconductor materials may have the same type of steps. On surfaces comprising GaN, gallium beads may appear on the surface during exposure to high temperature.

In order to obtain smooth surfaces, it is therefore sought to prevent the formation of terraces or to remove them in a later step, and, if necessary, prevent the appearance of beads of gallium or other material.

For example, mechanical or chemical mechanical polishing (CMP) may be carried out after the heat treatment. However, if the height of the terraces formed is too great, for example, greater than 80 nm between two consecutive plates, the thickness to be removed is too great and involves a long and laborious process. In addition, the remaining thickness is often too thin for the intended applications.

Another method is to use very fast annealing ramps to limit the appearance of terraces. This method requires very rapid temperature increases of approximately 400 °C per minute and is therefore not compatible with industrial furnaces.

Alternatively, a silane overpressure can be applied that limits the sublimation of silicon in SiC, thus avoiding the formation of terraces. This method is described in the article by R. Zhang et al. However, it requires the introduction of SiH₄ gas and equipment to create the overpressure. In addition, silicon droplets may appear on the SiC surface at temperatures above 1600 °C.

Another possibility to prevent the formation of terraces is to use a protective layer. The article by J. Bao et al. proposes a protective layer of carbon obtained by a method of centrifuging a resin on an SiC surface. The resin is annealed at 750 °C-900 °C to form a carbon film approximately 1 μm thick. This technique involves the addition of more steps in the forming process and the use of additional equipment and involves a risk of contamination of the substrate by the resin.

In some cases, the protective layer can also be formed of aluminum nitride (AlN). However, this material is difficult to remove, especially after heat treatment at a high temperature.

### BRIEF SUMMARY

One objective of the present disclosure is to provide a method for stabilizing a substrate having a surface of a semiconductor material, especially aimed at preventing the formation of terraces and/or beads by a step that is simple to implement. This stabilization treatment must be easy to integrate into the manufacturing method for a substrate comprising a surface of a semiconductor material and not present a risk of contamination of such a substrate.

To this end, the present disclosure proposes a method of stabilizing a surface of a semiconductor material, especially a monocrystalline semiconductor material, against the formation of terraces and/or beads, the method comprising the formation, on the surface, of a vitreous carbon layer in the gaseous phase at a pressure greater than or equal to 80 kPa (800 mbar).

In the present text, the surface that it is sought to stabilize is a free surface of the semiconductor material, i.e., an outer surface forming an interface with the external environment of a substrate comprising the semiconductor material.

Advantageously, the semiconductor material is silicon carbide.

Advantageously, the formation of the carbon layer is carried out at a temperature between 1000 °C and 1200 °C. Advantageously, the method further comprises a step of thickening the carbon layer at a temperature greater than the carbon layer formation temperature.

Preferably, the carbon layer has a thickness between 5 nm and 500 nm, preferably between 50 nm and 150 nm.

In some embodiments, the carbon layer is deposited in a gas flow comprising a carbon-containing gas and a carrier gas, the carrier gas preferably being argon or a mixture of argon and hydrogen.

In other embodiments, the carbon layer is deposited by evaporating carbon-containing gas from a solid carbon source.

In some embodiments, the carbon layer is formed in a substrate annealing furnace. Preferably, the annealing furnace comprises inner walls and support members configured to hold at least one substrate, the inner walls, supports, and the gas within the annealing furnace having the same temperature.

Advantageously, the annealing furnace contains a plurality of substrates comprising a surface of the semiconductor material, the substrates being superposed vertically, a vertical space being provided between two adjacent substrates, a carbon layer being formed on the surface of the semiconductor material of each of the substrates.

In other embodiments, the carbon layer is deposited in a chemical vapor deposition chamber.

The present disclosure also relates to a method of treating a substrate having a free surface of a semiconductor material, especially a monocrystalline semiconductor material, comprising a method of stabilizing the surface as described above and a heat treatment of the substrate after stabilizing the surface.

Advantageously, at least part of the heat treatment is carried out at a temperature above 1700 °C.

In some embodiments, the deposition of the carbon layer and the heat treatment are performed in the same substrate annealing furnace. Preferably, the heat treatment comprises, successively, a first phase carried out at a temperature between 1000 °C and 1200 °C, comprising the formation of the carbon layer, and at least a second phase carried out at a temperature greater than 1200 °C, preferably greater than 1700 °C, in which the carbon layer formed during the first phase limits the reorganization of the surface into a semiconductor material in the form of terraces. Advantageously, the method further comprises, after the heat treatment, a step of removing the carbon layer by reactive ion etching or by plasma etching. Advantageously, the method comprises a step of injecting oxygen into the furnace to create a reactive plasma during the step of removing the carbon layer.

The present disclosure also relates to a method for manufacturing a semiconductor structure, comprising the following steps:
formation of a weakened area by implantation of ionic species in a donor substrate made of a semiconductor material, especially a monocrystalline semiconductor material,
bonding of the donor substrate to a support substrate,
detachment of the donor substrate along the weakened area so as to transfer a layer of semiconductor material onto the support substrate, and
a treatment method as described above so as to heal defects created in the layer of semiconductor material during implantation of ionic species, wherein the carbon layer is formed on the free surface of the layer of semiconductor material transferred to the support substrate.

Preferably, the donor substrate is made of silicon carbide.

### BRIEF DESCRIPTION OF THE DRAWINGS

Other characteristics and advantages of the embodiments of the present disclosure will result from the detailed description that follows, with reference to the attached drawings, in which:

FIG. 1 shows the formation of terraces on a front face of a monocrystalline semiconductor material.

FIG. 2 shows a substrate comprising a portion made of a monocrystalline semiconductor material on its front face.

FIG. 3 shows the substrate of FIG. 2 after deposition of a carbon layer.

FIG. 4 shows the substrate of FIG. 3 after ablation of a carbon layer.

FIGS. 5A to 5C show a substrate comprising a portion made of a monocrystalline semiconductor material on its front face.

FIG. 6 shows the thermal profile used for a method according to the present disclosure.

FIG. 7 shows the roughness induced by the terraces as a function of the annealing temperature for different substrates.

FIG. 8 illustrates an annealing furnace suited to forming a carbon layer according to a preferred embodiment of the present disclosure.

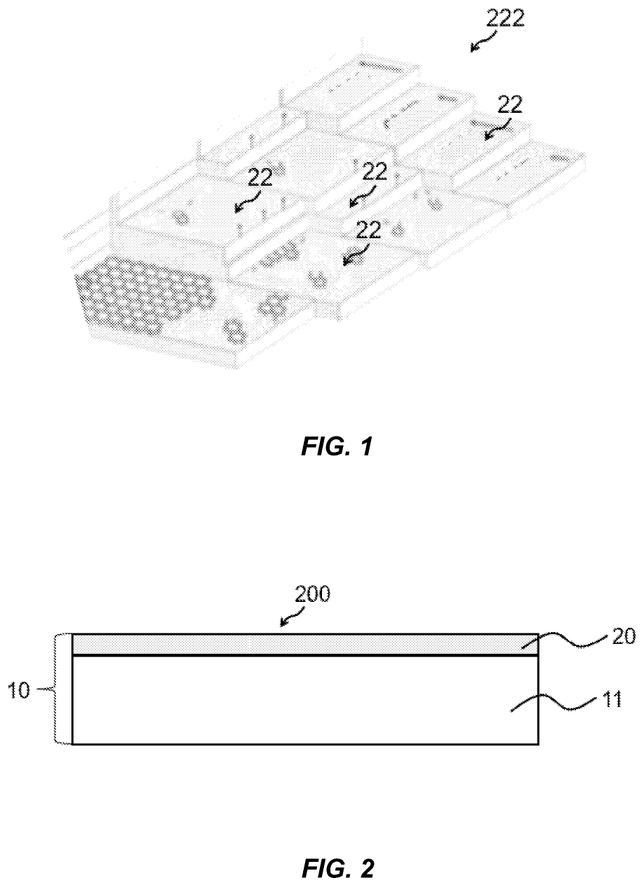

### DETAILED DESCRIPTION

FIG. 2 shows a substrate 10 comprising a support substrate 11 and a portion 20 of a monocrystalline semiconductor material on its front face. The support substrate 11 may be any type of support substrate suitable for depositing or transferring a portion 20 made of a monocrystalline semiconductor material, for example, a support substrate made of a polycrystalline semiconductor material.

Alternatively, the substrate 10 may be a solid substrate made of a monocrystalline semiconductor material, i.e., the support substrate 11 and the portion 20 together constitute a single portion made of a solid monocrystalline semiconductor material.

It should be noted that the semiconductor material that forms the front face of the substrate 10, and which therefore composes either the portion 20 (in the case of a substrate 10 comprising a support substrate 11 and a portion 20) or the substrate 10 (in the case of a solid substrate), is also capable of being a polycrystalline material.

In the remainder of the description, since the case of a substrate 10 comprising a support substrate 11 and a monocrystalline portion 20 is described in detail, the material constituting the portion 20 will be designated by the expression “monocrystalline semiconductor material” in order to distinguish it from the material constituting the support substrate 11. However, the method described below is also applicable to the case of a polycrystalline semiconductor material, each grain then being capable of being considered as a single crystal.

According to a preferred embodiment, the monocrystalline semiconductor material is silicon carbide.

According to other embodiments, the monocrystalline semiconductor material is chosen from: aluminum nitride (AlN), gallium nitride (GaN), alloys of these nitrides AlₓGA₍₁₋ₓ₎N, where x is a number between 0 and 1, indium phosphide (InP) or gallium arsenide (GaAs).

Typically, the surface 200 of the portion 20 made of a monocrystalline semiconductor material or, as applicable, of the substrate made of a solid monocrystalline semiconductor material, is slightly misaligned. For example, if the semiconductor material is SiC, the surface may be misaligned with regard to the crystal structure of SiC to facilitate control of the 4H polytype during growth.

In the case of a polycrystalline semiconductor material, some of the grains may have such a misalignment with respect to the crystalline structure of SiC. For example, following the cutting or polishing of the substrate 10 so as to reveal a specific face of the substrate 10, grains that are oriented randomly with respect to this face will be misaligned.

### Formation of the Protective Layer

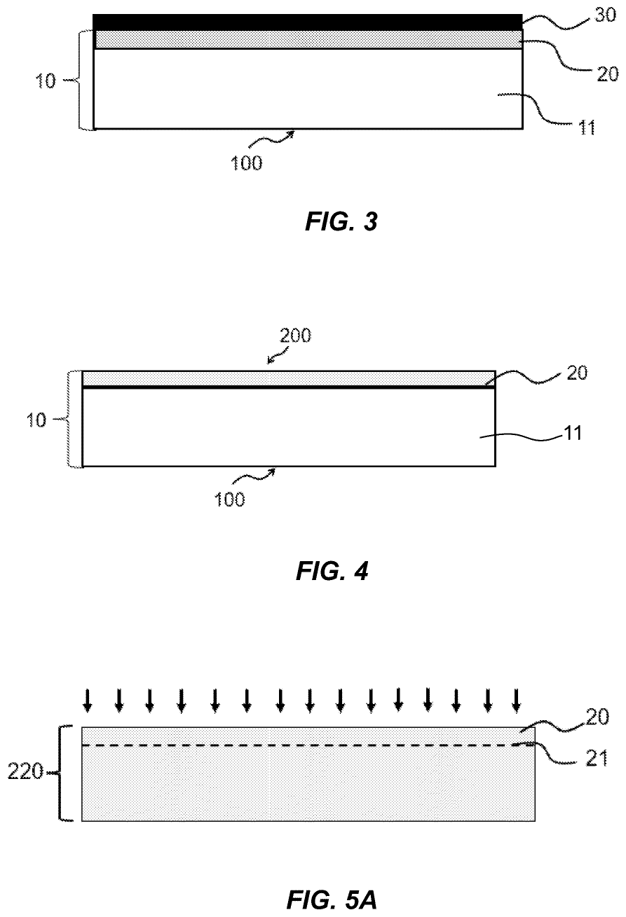

With reference to FIG. 3, a carbon layer 30 is subsequently formed on the surface 200 of the portion 20 made of a monocrystalline semiconductor material.

Preferably, the carbon layer 30 is made of vitreous carbon. Alternatively, the carbon layer 30 may be in another form of carbon, for example, amorphous carbon, graphene or diamond.

The carbon layer 30 is continuous and covers the entire surface to be protected, i.e., the front face of the monocrystalline material.

The carbon layer 30 protects the surface of the substrate from terracing when heated to high temperature. It thus stabilizes the crystal structure of the surface. The carbon layer 30 is removed after completion of the high temperature treatments to obtain a clean surface of the monocrystalline semiconductor material of good crystal quality. The thickness of the carbon layer is preferably less than 200 nm to allow easy removal at the end of a high temperature process.

In the case of a vitreous carbon layer, the vitreous character is obtained from a carbon thickness of a few nanometers; for a smaller thickness, the carbon is in the form of one or two monolayers of graphene. When the thickness is sufficient to produce glassy carbon, the protective layer has a long-distance scale, unorganized three-dimensional structure, which is stable over the entire temperature range to which the surface is exposed during the process, and which allows total coverage of the substrate surface. The uniformity of a vitreous carbon layer is easier to control over the surface area of the substrate.

Advantageously, the thickness of the protective carbon layer 30 is between 50 nm and 150 nm.

Advantageously, the formation of the carbon layer 30 is carried out in a deposition chamber, which will be described below. The carbon layer 30 is formed in the gaseous phase, i.e., the carbon is present in the deposition chamber in gaseous form. The substrate is heated in the deposition chamber to a deposition temperature of the protective layer, and the carbon gas phase is transformed into solid carbon by reaction with the hot surface of the substrate.

The temperature and the pressure of the gas in the deposition chamber are chosen so as not to cause degradation of the surface to be protected during deposition of the carbon layer 30.

Advantageously, the carbon source is a carbon-containing gas, for example, propane (C₃H₈) or acetylene (C₂H₄) gas mixed with a carrier gas, for example, argon or a mixture of argon and hydrogen. The flow rate of such a carbon source can be easily controlled and adjusted to the deposition conditions of the carbon layer. The carrier gas is a neutral gas that is not involved in the chemical reaction of layer formation. The use of such a gas makes it possible to increase the pressure in the deposition chamber to a value greater than or equal to 80 kPa (800 mbar), which limits surface recombinations during the deposition of the carbon layer and thus prevents the formation of terraces during the deposition of the carbon layer 30.

The use of a high pressure and a high flow of carrier gas also makes it possible to achieve better homogeneity of the carbon and better uniformity of the temperature inside the deposition chamber, and to carry out the deposition homogeneously on a plurality of superposed substrates in the same deposition chamber. During the deposition of the carbon layer, the atmosphere in the deposition chamber is free of oxygen. Moreover, unlike known deposition processes, this process does not use any primary or secondary vacuum steps. This process is therefore faster and simpler than processes that require such vacuums, since it is not necessary to provide a pumping time for the chamber, heat exchanges are facilitated therein and it is not necessary to provide complex equipment.

The mixture of the carbon-containing gas with the carrier gas is carried out at a percentage of the carbon-containing gas of 0.01% to 10%, ideally 0.1% to 1%. For example, propane diluted in a 1% argon carrier gas can be used. Such a concentration is relatively low and makes it possible to prevent saturating the atmosphere of the deposition chamber, which allows better control of the thickness of the deposited carbon layer. Thus, even if there is an additional source of carrier gas to achieve the desired pressure, only low concentrations of carbon-containing gases such as propane or acetylene are used, which involves a lower risk of contamination and is less harmful to the deposition chamber and substrate.

Alternatively, the carbon layer can be deposited from another carbon source, for example, a solid source placed in the same chamber as the substrate. Such a solid source is, for example, a quantity of resin deposited on a substrate made of a semiconductor material and then crosslinked in a furnace or on a heating plate. In this case, the evaporation, in the deposition chamber, of carbon-containing gas or gases present in the resin is sufficient to generate, in the atmosphere, a concentration sufficient to cause a layer of carbon to appear on the surfaces made of a semiconductor material.

The carbon layer can be characterized by surface analysis techniques such as atomic force microscopy (AFM), X-ray reflectometry (XRR), Raman spectroscopy or low energy electron microscopy (LEEM).

The carbon layer is stable at least up to a temperature of 2000 °C and limits the formation of terraces while the substrate is exposed to a temperature above the terrace-forming temperature.

### High Temperature Steps Requiring the Protective Layer

After the formation of the carbon layer, further steps can be carried out on the substrate at a temperature higher than the terrace-forming temperature. Such steps are, for example, annealing to heal defects in the crystal lattice caused during implantation of ionic species, to modify the crystal structure of the substrate, or to activate dopants. During these steps, the surface of the monocrystalline semiconductor material is protected by the carbon layer and the formation of terraces on the surface is prevented. The annealing steps are carried out at temperatures between 1300 °C and 2000 °C, typically above 1700 °C.

### Removal of the Protective Layer

At the end of the annealing steps, the temperature is lowered to a temperature below the terrace-forming temperature, i.e., below 1300 °C. Advantageously, the temperature is lowered to 900 °C for ablation of the carbon layer. The carbon layer can then be removed because the temperature is low enough that no terracing occurs on the surface of the semiconductor material. The small thickness of the carbon layer promotes rapid and residue-free removal on the substrate.

The carbon layer can be removed by a reactive plasma, for example, an oxygen plasma according to the reaction:

C(solid)+O₂(gaseous)→CO₂(gaseous)

In some cases, the removal can be carried out in the same deposition chamber as the one in which the steps of forming the protective carbon layer and/or the high temperature steps have been carried out. However, if elements of the deposition chamber are made of unprotected graphite or other materials that can be damaged by contact with the reactive plasma, it is preferable to transfer the substrate to another chamber for removal of the carbon layer.

Alternatively, the carbon layer can be removed by reactive ion etching (RIE), for example, by oxygen ions or a mixture of oxygen and sulfur hexafluoride.

In some cases, the carbon layer is removed during a substrate finishing step, such as a mechanical polishing step, without a specific removal step.

In order to remove any carbon residues and/or to ensure a good quality of the surface of the monocrystalline semiconductor material, a suitable chemical mechanical polishing step can be carried out after the removal of the carbon layer.

At the end of this step, with reference to FIG. 4, the substrate 11 is finalized and the carbon layer is removed. It is now possible to use the substrate 11 and the free surface of the monocrystalline semiconductor material for the epitaxial growth of a layer of a monocrystalline semiconductor material (identical to or different from that of the substrate 11) and/or for the manufacture of an electronic power or radiofrequency component.

### Conducting a Manufacturing Method for a Semiconductor Structure

A method will now be described for manufacturing a semiconductor structure for electronic applications, having a monocrystalline silicon carbide surface.

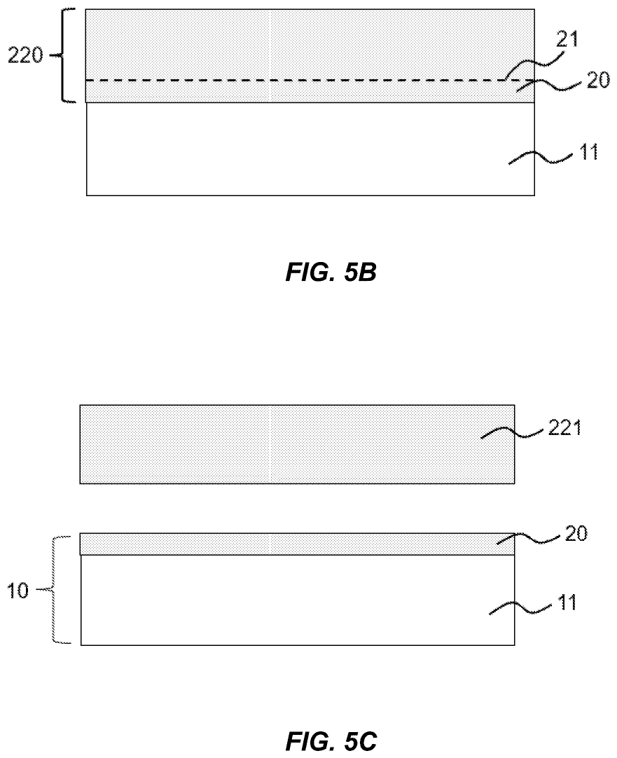

A monocrystalline silicon carbide donor substrate 220 is provided from which the monocrystalline silicon carbide surface layer will be formed. With reference to FIG. 5A, as shown schematically by the arrows, an ionic species, such as hydrogen and/or helium, is implanted so as to form a weakened area 21 in the donor substrate 220. The weakened area 21 defines a layer 20 of monocrystalline silicon carbide to be transferred.

With reference to FIG. 5B, the donor substrate 220 thus implanted is bonded to a base substrate 11. The donor substrate may be bonded directly to the base substrate as illustrated in FIG. 5B, or via one or more intermediate layers that may be arranged on the donor substrate and/or on the base substrate before bonding (not shown).

With reference to FIG. 5C, the donor substrate 220 is then detached along the weakened area 21, which leads to the transfer of the monocrystalline silicon carbide layer onto the base substrate 11, thus forming the support substrate 10 as shown in FIG. 2. The detached portion 221 of the donor substrate can be reused for the transfer of other monocrystalline silicon carbide layers onto other base substrates.

A treatment process is then carried out, successively comprising a step of stabilizing the surface by the formation of a protective carbon layer, a high temperature annealing intended to heal the defects created in the monocrystalline silicon carbide layer during the implantation of the ionic species, and the subsequent removal of the protective carbon layer.

In some embodiments, the method of processing a substrate having a single crystal silicon carbide surface is performed in a single annealing furnace. In this case, the carbon layer is also deposited in the annealing furnace. Thus, a transfer from a deposition chamber dedicated to the deposition of the protective layer to an annealing furnace is avoided during the process in progress, and thus a simpler, faster process is obtained without risk of substrate contamination.

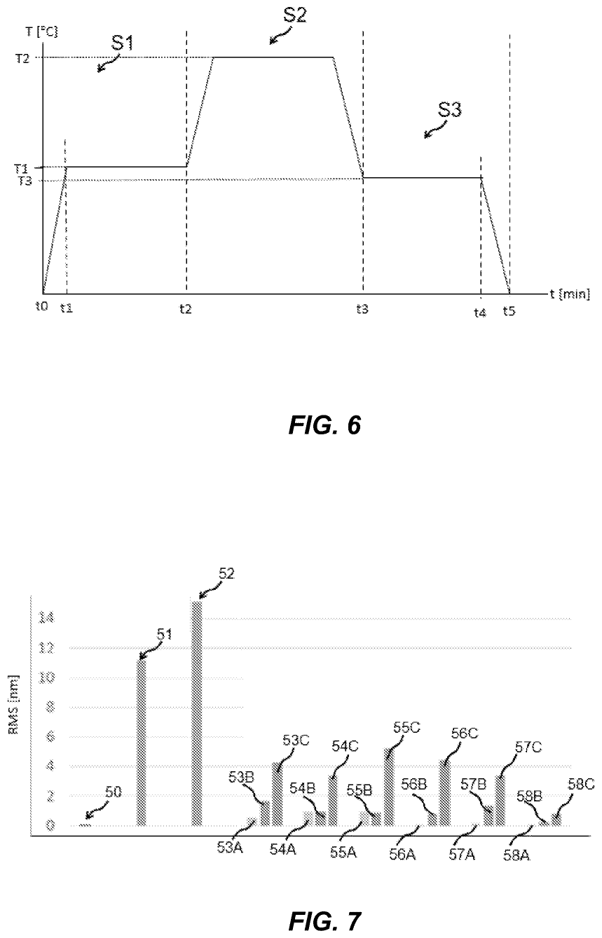

FIG. 6 illustrates a temperature profile for such a process in an annealing furnace as a function of elapsed time. Three main process sequences can be distinguished, corresponding to the formation of a protective carbon layer (S1), a high temperature annealing (S2), i.e., above the temperature at which the formation of terraces begins, and a step of removing the protective layer (S3).

The gas injected at the top of the furnace is evacuated under a flow of carrier gas and evacuated through the bottom of the furnace during all the sequences of the process.

The first sequence S1 starts at a time t0. The substrate is at room temperature, which is typically approximately 20 °C or at a temperature below the terrace-forming temperature. The substrate is introduced into the deposition chamber. Heating the substrate to a carbon layer deposition temperature T1 is started. The deposition temperature T1 is between 1000 °C and 1200 °C. Thus, T1 is lower than the temperature at which the formation of terraces begins, which is approximately 1300 °C at a pressure of 101 kPa (1 atm).

The deposition temperature T1 is kept constant and the carbon layer is deposited. During this time, the pressure in the furnace is maintained at 80 kPa (800 mbar) or 100 kPa (1 bar).

The duration of formation of the carbon layer is typically between 10 and 30 minutes. The flow rate of propane injected to obtain the carbon-containing gas depends on the volume of the chamber and is, for example, approximately 10 SCCM. These parameters can be adjusted to obtain a carbon layer with a desired thickness and homogeneity suitable for optimal protection during the next sequence, and for a time sufficiently short to optimize the process in terms of time and cost.

### Deposition of the Carbon Layer Begins at a Time t1.

In some cases (not shown), the deposition of the carbon layer is followed by a step of thickening the carbon layer at a temperature higher than T1. The step S1 thus comprises several different temperature stages. The use of a first stage makes it possible to obtain a protective layer at a temperature at which the formation of terraces is very low and therefore negligible. The use of a second stage at a higher temperature results in faster growth to thicken the carbon layer.

The carbon-containing gas supply is stopped at the end of the sequence S1. The residues of the carbon-containing gas are evacuated under the carrier gas flow.

When the deposition of the carbon layer is completed at a time t2, the second sequence S2 is carried out. The second sequence S2 comprises heating from the deposition temperature T1 to an annealing temperature T2 and a temperature plateau of a duration, which is typically between 30 and 120 min. The annealing temperature T2 and the duration of the treatment are chosen according to the state and the substrate before the process in progress, and the crystal structure of the envisaged substrate. Typically, the annealing is carried out at a temperature T2 between 1600 °C and 2000 °C.

At the end of the sequence S2, the substrate is cooled to preserve the crystalline properties obtained during annealing. At a time t3, the substrate reaches a third temperature T3 of 900 °C.

The third sequence S3 is then carried out during which the protective carbon layer is removed by oxidation, as described previously. During this step, the temperature T3=900 °C is kept constant. The duration of the removal is typically between 10 and 120 s at a stripping rate of approximately 100 nm per minute. The total duration of the sequence S3 also comprises stabilization of the furnace and is between 5 and 60 min. When, at time t4, the carbon layer is completely removed, the substrate is cooled in order to remove it from the furnace.

Alternatively, the protective layer can be deposited in a chemical vapor deposition chamber. In this case, a step of transfer from the deposition chamber to the substrate annealing furnace is added at time 2. This step typically involves cooling the substrate and subsequent heating.

In some embodiments, when components of the annealing furnace should not be exposed to an oxygen atmosphere, a step of transfer from the annealing furnace to a protective layer removal chamber is added. The removal chamber can be designed to remove the layer by reactive ion etching or plasma etching. Such a step involves cooling the substrate at t3 and heating to the removal temperature at the beginning of the sequence S3.

When the substrate treatment process comprises a transfer step, the different sequences can be carried out separately in time.

### Effect of the Protective Layer on the Formation of Terraces

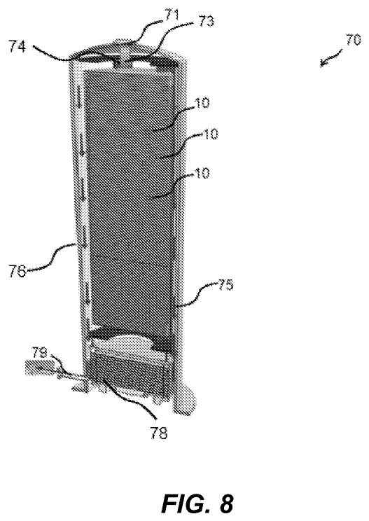

FIG. 7 shows the root mean square (RMS) value of the surface roughness generated by the formation of terraces on a monocrystalline SiC surface measured by AFM. In this example, the presence of a carbon protective layer was confirmed by Raman spectroscopy measurements.

The bar 50 corresponds to a reference measurement of a monocrystalline SiC layer with an orientation in the crystalline axis C with an offset of 4° in the direction [11-20] of the silicon carbide crystal, not covered with a carbon layer and not having undergone any heat treatment liable to generate terraces. All other measurements are carried out on samples of the same orientation and the same crystal quality of SiC.

The bars 51 and 52 correspond to monocrystalline SiC samples without a protective carbon layer. The sample corresponding to bar 51 was annealed at 1635 °C and the sample corresponding to bar 52 was annealed at 1765 °C. All annealing is 30 minutes long. A formation of terraces with steps responsible for a surface roughness greater than 11 nm RMS or 15 nm RMS, respectively, is observed, which can be a problem for the manufacture of electronic components.

The conditions of formation of the carbon layer are summarized in Table 1.

TABLE 1

| | Temperature | Stage | Pressure | Atmosphere/Environment |
|---|---|---|---|---|
| 53A to 53C | 1300 °C | 10 | 80 kPa | 10 SCCM C₃H₈//H₂/Ar: |
| | | min | (800 mbar) | 1/10 |
| 54A to 54C | 1300 °C | 10 | 80 kPa | 10 SCCM C₃H₈//H₂/Ar: |
| | | min | (800 mbar) | 0/10 |
| 55A to 54C | 1200 °C | 10 | 80 kPa | 10 SCCM C₃H₈//H₂/Ar: |
| | | min | (800 mbar) | 0/10 |
| 56A to 56C | 1000 °C | 10 | 80 kPa | 10 SCCM C₃H₈//H₂/Ar: |
| | | min | (800 mbar) | 0/10 |
| 57A to 57C | 1200 °C | 10 | 80 kPa | 10 SCCM C₃H₈//H₂/Ar: |
| | | min | (800 mbar) | 12/0 |
| 58A to 58C | 1200 °C | 30 | 80 kPa | 10 SCCM C₃H₈//H₂/Ar: |
| | | min | (800 mbar) | 0/10 |

The bars 53A to 58C correspond to samples on which a protective carbon layer has been deposited according to the parameters indicated in Table 1. In the case of bars 53A to 57C, the duration of the stage is 10 minutes. For bars 58A-58C, the duration of the stage is 30 minutes.

The bars 53A, 54A, 55A, 56A, 57A and 58A correspond to different samples on which a protective carbon layer has been deposited and subsequently removed.

These samples were not annealed. For measurements 53A, 54A, and 55A, the formation of terraces is slightly above the reference measurement, however the roughness remains less than 1 nm RMS. Measurements 56A, 57A and 58A result in roughness comparable to that of the reference.

For the bars 53B, 54B, 55B, 56B, 57B and 58B, a protective carbon layer was deposited on a monocrystalline SiC surface according to the conditions of Table 1, and annealing at 1700 °C was carried out. The annealing lasted between 30 and 60 minutes. Subsequently, the carbon layer was removed for RMS measurement. For all the samples, the roughness is less than 2 nm RMS.

For the bars 53C, 54C, 55C, 56C, 57C and 58C, a protective carbon layer was deposited on a monocrystalline SiC surface according to the conditions of Table 1, and annealing at 1800 °C was carried out. Subsequently, the carbon layer was removed for RMS measurement. For all samples, the roughness is less than 5 nm RMS.

A considerable reduction in the formation of terraces is thus observed for all the carbon layers deposited. The most favorable results were obtained for the samples 58A-58C for which the deposition time of the carbon-containing layer is 30 minutes, which is greater than the formation time of the other protective layers. Depending on the need to reduce the step bunching, the duration of the process and the temperature of the annealing envisaged and the duration of the annealing required, the parameters of the deposition of the protective layer can be adjusted in order to reduce the appearance of terraces as much as possible without unnecessarily prolonging the process.

In another example, a GaN layer is transferred onto a support substrate such as a polycrystalline silicon carbide, polycrystalline aluminum nitride or another semiconductor support substrate. A protective carbon layer is deposited by a process as described above on the free surface of the GaN layer. Since the formation of gallium beads is liable to take place from a temperature of 850 °C under a nitrogen atmosphere at atmospheric pressure, the deposition of the carbon layer is, for example, carried out at a temperature below 800 °C. However, higher temperature deposits are also able to occur in certain circumstances, for example, if a high gallium partial pressure limits the appearance of gallium beads.

A heat treatment can then be carried out to activate the dopants present in the GaN layer and/or to reinforce the bonding following the transfer of the GaN layer. During the heat treatment, the GaN surface is protected from terracing and gallium bead formation.

The carbon layer is then removed by reactive ion etching or plasma etching and/or chemical mechanical polishing.

### Presentation of the Furnace

In order to make a process for treating a plurality of substrates efficient and fast, it is preferable to use an annealing furnace that can simultaneously treat a maximum of substrates under identical conditions. Such a furnace is conventionally called a batch anneal furnace in the field of microelectronics.

FIG. 8 illustrates a furnace 70 designed to receive a quantity of between 120 and 150 substrates in an annealing chamber. The substrates 10 are positioned horizontally in the furnace 70 and are superposed vertically so as to treat as many substrates as possible in the same hot gas flow 73. A free space is maintained between each substrate 10 and the adjacent substrates 10 in order to optimize the gas flow and facilitate the formation of the carbon layer.

Such a furnace 70 uses a top flow configuration, i.e., a gas flow is conveyed into the furnace 70 through the top 71 and, after passing through the furnace 70, is discharged through an outlet 79 at the bottom of the furnace. Typically, a gas flow called carrier gas transports the carbon-containing gas (typically propane) for the formation of the carbon-containing layer. In certain cases, other gases are added into the furnace 70, for example, catalyst gases to promote the decomposition of the carbon-containing gas.

When a solid source is used, it is, for example, disposed at the top of the furnace 70, so that the carrier gas transports the carbon-containing gases from the solid source to the substrates to be coated located downstream. However, the position of the solid source may vary.

All the components of the annealing chamber inside the furnace 70, i.e., the inner walls 75, the substrate holders for holding the substrates in a horizontal and vertically superposed position, and the gas contained in the annealing chamber are at the same temperature during use of the furnace, except for the external elements such as the outer wall 76 and the ends of the gas inlet pipes. The same temperature means that the temperature difference between the end 74 of the top of the furnace and the end 78 of the bottom of the furnace is minimal, typically a few degrees C, for example, less than 3 degrees for a temperature in the furnace between 800 and 1200 °C.

The substrates are heated mainly by conduction from the walls of the furnace. The gas flows are injected at the same temperature as the temperature inside the furnace.

An annealing furnace 70 is not intended for the deposition of layers but rather for the application of a heat treatment of the substrates placed in the furnace. These furnaces are therefore optimized for a high temperature homogeneity of the substrates received therein, but not to allow optimization of a material deposition, especially to ensure a homogeneity of gas flow on the surface of the substrates. The superposed positioning of substrates is especially detrimental to this homogeneity since the gases have more difficulty accessing the center of the substrates than the edges of the substrates. However, this type of furnace nevertheless lends itself to the deposition of carbon layers to protect the surface of a semiconductor material against the formation of terraces, especially because the homogeneity of the thickness of the carbon layer is not a determining criterion as long as the entire surface to be protected is covered. The temporary use of the carbon layer does not require an increased homogeneity of this layer. However, it is necessary to control the thickness so as to obtain sufficient thickness over the surface area of all substrates contained in the furnace.

Unlike an epitaxy chamber, such a furnace allows a large number of substrates to be treated simultaneously by means of the vertical superposition arrangement. Moreover, such a furnace makes it possible to carry out the step of depositing the carbon layer and the annealing in the same chamber, which avoids a risk of contamination during transfer between two different chambers. Transfer steps between a carbon layer deposition chamber and an annealing furnace are avoided, thus avoiding cooling between the respective steps, the need for manpower for the transfer and thus a loss of time and efficiency.

### REFERENCES

R. Zhang et al. “Growth of large Domains of Epitaxial Graphene on the C-face of SiC,” J. of App. Phys. 2012, 112 (10); doi: 10.1063/1.4765666
J. Bao et al. “Sequential Control of Step-Bunching During Graphene Growth on SiC (0001),” App. Phys. Lett. 2016, 109(8); doi: 10.1063/1.4961630

1. A method of stabilizing a surface of a semiconductor material, comprising forming, on the surface, a vitreous carbon layer in a gaseous phase at a pressure greater than or equal to 80 kPa.

2. The method of claim 1, wherein the semiconductor material is silicon carbide.

3. The method of claim 1, wherein the formation of the carbon layer is carried out at a carbon layer formation temperature comprised between 1000 °C and 1200 °C.

4. The method of claim 3, further comprising thickening the carbon layer at a temperature higher than the carbon layer formation temperature.

5. The method of claim 1, wherein the carbon layer has a thickness between 5 nm and 500 nm.

6. The method of claim 1, wherein the carbon layer is deposited in a gas flow comprising a carbon-containing gas and a carrier gas.

7. The method of claim 1, wherein the carbon layer is deposited by evaporating carbon-containing gas from a solid carbon source.

8. The method of claim 1, wherein the carbon layer is formed in a substrate annealing furnace.

9. The method of claim 8, wherein the annealing furnace includes inner walls and support members configured to hold at least one substrate, the inner walls, the supports, and a gas within the annealing furnace having the same temperature.

10. The method of claim 8, wherein the annealing furnace contains a plurality of substrates comprising a surface of the semiconductor material, the substrates being vertically superposed, a vertical space being provided between two adjacent substrates, a carbon layer being formed on the surface of the semiconductor material of each of the substrates.

11. The method of claim 1, wherein the carbon layer is formed in a chemical vapor deposition chamber.

12. A method of treating a substrate having a free surface of a semiconductor material, comprising stabilizing the surface with the method according to claim 1 and carrying out a heat treatment of the substrate after stabilizing the surface.

13. The method of claim 12, wherein at least part of the heat treatment is carried out at a temperature greater than 1700 °C.

14. The method of claim 12, wherein the carbon layer is deposited in a gas flow comprising a carbon-containing gas and a carrier gas and the deposition of the carbon layer and the heat treatment are carried out in the same substrate annealing furnace.

15. The method of claim 14, wherein the heat treatment comprises, successively, a first phase carried out at a temperature between 1000 °C and 1200 °C, comprising the formation of the carbon layer, and at least a second phase carried out at a temperature greater than 1200 °C, wherein the vitreous carbon layer formed during the first phase limits the reorganization of the surface into a semiconductor material in the form of terraces.

16. The method of claim 14, further comprising, after the heat treatment, removing the carbon layer by reactive ion etching or plasma etching.

17. The method according to claim 16, comprising a step of injecting oxygen into the furnace to create a reactive plasma during the step of removing the carbon layer.

18. The method of claim 12, further comprising removing the carbon layer by chemical mechanical polishing.

19. A manufacturing method for a semiconductor structure, comprising:
forming a weakened area by implantation of ionic species in a donor substrate made of a semiconductor material;
bonding of the donor substrate to a support substrate;
detaching the donor substrate along the weakened area so as to transfer a layer of semiconductor material onto the support substrate; and
carrying out a method according to claim 11 so as to heal defects created in the layer of semiconductor material during implantation of ionic species, wherein the carbon layer is formed on a free surface of the layer of semiconductor material transferred to the support substrate.

20. The manufacturing method of claim 19, wherein the donor substrate is silicon carbide.
